(19) United States
(12) Patent Application Publication
(10) Pub. No.: US 2025/0372946 A1
(43) Pub. Date: Dec. 4, 2025

(54) LIGHT EMITTING DEVICE AND RANGING DEVICE

(71) Applicant: CANON KABUSHIKI KAISHA, Tokyo (JP)

(72) Inventors: KAZUYA KAYAMA, Tokyo (JP); TAKEAKI ITSUJI, Kanagawa (JP)

(21) Appl. No.: 19/217,486

(22) Filed: May 23, 2025

(30) Foreign Application Priority Data
May 29, 2024 (JP) 2024-087187

(51) Int. Cl. H01S 5/062; G01S 7/481

(52) U.S. Cl. CPC H01S 5/062; G01S 7/4814

(57) ABSTRACT

A light emitting device includes a light emitting element configured to emit light including a laser light and a steady oscillation light having a light intensity smaller than a light intensity of the laser light, a light receiving element configured to send a switching signal when receiving a part of the light, and a power supply control unit configured to control a power supply voltage to be applied to the light emitting element. The power supply control unit controls the power supply voltage to a first power supply voltage to emit the laser light from the light emitting element, and then controls the power supply voltage to a second power supply voltage smaller than the first power supply voltage in response to the switching signal.

### BACKGROUND

### Field of the Technology

The aspect of the embodiments relates to a light emitting device and a ranging device.

### Description of the Related Art

Conventionally, a ranging method called a light time-of-flight (TOF) method is known as one of ranging methods for measuring a distance to an object using light. As a light emitting element for ToF LiDAR (Light Detection and Ranging), a VCSEL (Vertical Cavity Surface Emitting Laser) may be used. In International Publication No. WO2022/123974, a ranging device using the VCSEL is disclosed.

However, the ranging device of International Publication No. WO2022/123974 includes an undesired light having a small contribution to the ranging operation in the light emitted from the light emitting element.

### SUMMARY

According to an aspect of the embodiments, there is provided a light emitting device including: a light emitting element configured to emit light including a laser light and a steady oscillation light having a light intensity smaller than a light intensity of the laser light; a light receiving element configured to send a switching signal when receiving a part of the light; and a power supply control unit configured to control a power supply voltage to be applied to the light emitting element, wherein the power supply control unit controls the power supply voltage to a first power supply voltage to emit the laser light from the light emitting element, and then controls the power supply voltage to a second power supply voltage smaller than the first power supply voltage in response to the switching signal.

Further features of the disclosure will become apparent from the following description of exemplary embodiments with reference to the attached drawings. The following description of embodiments are described by way of example.

### BRIEF DESCRIPTION OF THE DRAWINGS

FIG. 1 is a block diagram of a light emitting device according to a first embodiment.

FIG. 2 is a cross-sectional view of the light emitting device according to the first embodiment.

FIGS. 3A and 3B are circuit diagrams of a power supply switching unit according to the first embodiment.

FIGS. 4A, 4B, 4C, 4D, and 4E are waveform diagrams of a power supply voltage applied to a light emitting element according to the first embodiment.

FIG. 5 is a waveform diagram of a laser pulse light according to a comparative example.

FIG. 6 is a waveform diagram of a laser pulse light according to the first embodiment.

FIG. 7 is a diagram illustrating a relationship between a waveform of a laser pulse light and a power supply voltage according to the first embodiment.

FIG. 8 is a time chart of the light emitting device according to the first embodiment.

FIG. 9 is a block diagram of a light emitting device according to a second embodiment.

FIG. 10 is a cross-sectional view of the light emitting device according to the second embodiment.

FIG. 11 is a circuit diagram of a power supply switching unit according to the second embodiment.

FIG. 12 is a diagram illustrating a relationship between an RC value and a power supply voltage according to the second embodiment.

FIG. 13 is a block diagram of a light emitting device according to a third embodiment.

FIG. 14 is a cross-sectional view of the light emitting device according to the third embodiment.

FIG. 15 is a block diagram of a delay changing unit according to the third embodiment.

FIG. 16 is a diagram illustrating a relationship between a drive current, a path, and a delay time according to the third embodiment.

FIGS. 17A, 17B, 17C, and 17D are waveform diagrams of a laser pulse light according to the third embodiment.

FIG. 18 is a cross-sectional view of a light emitting device according to a fourth embodiment.

FIGS. 19A and 19B are diagrams illustrating a movable body according to a fifth embodiment.

FIG. 20 is a block diagram of an equipment according to a sixth embodiment.

### DESCRIPTION OF THE EMBODIMENTS

### First Embodiment

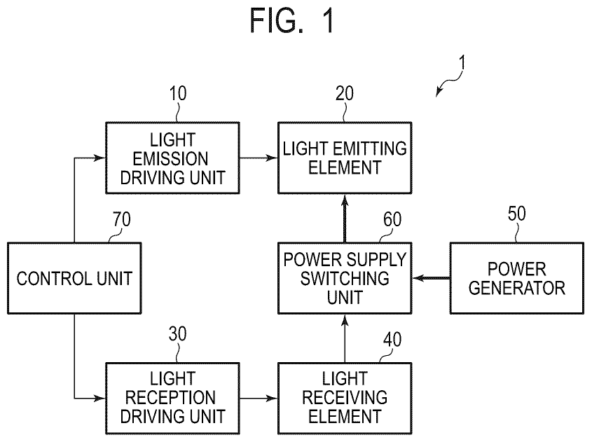

FIG. 1 is a block diagram of a light emitting device 1 according to the present embodiment.

In FIG. 1, the light emitting device 1 includes a light emission driving unit 10, a light emitting element 20, a light reception driving unit 30, a light receiving element 40, a power generator 50, a power supply switching unit 60, and a control unit 70. The light emission driving unit 10 and the light reception driving unit 30 are connected to the control unit 70, the light emitting element 20 is connected to the light emission driving unit 10 and the power supply switching unit 60, the light receiving element 40 is connected to the light reception driving unit 30, and the power supply switching unit 60 is connected to the light receiving element 40 and the power generator 50.

The light emission driving unit 10 is a driver circuit that drives the light emitting element 20. The light emission driving unit 10 controls a cathode voltage of the light emitting element 20 based on a control signal from the control unit 70.

The light emitting element 20 is a light source that emits light, and may be, for example, a solid-state laser or a semiconductor laser. In one embodiment, when miniaturization or power saving of the light emitting device 1 is required, the light emitting element 20 is a semiconductor laser. The semiconductor laser is a laser diode having an anode and a cathode and may be an edge emitting laser (EEL) or a surface emitting laser (SEL). In one embodiment, when two-dimensional array or high-speed modulation is required, the surface emitting laser is a vertical cavity surface emitting laser (VCSEL). The laser pulse light emitted from the VCSEL includes, for example, a high peak value pulse light (laser light) and a steady oscillation light following the high peak value pulse light. In the following description, the light emitting element 20 will be described as a VCSEL that emits the laser pulse light including the high peak value pulse light. The light emitting element 20 is supplied with power from the power generator 50 via the power supply switching unit 60 and emits the laser pulse light based on a control signal from the light emission driving unit 10.

The light reception driving unit 30 is a driver circuit that drives the light receiving element 40. The light reception driving unit 30 drives the light receiving element 40 based on a control signal from the control unit 70.

The light receiving element 40 may be, for example, a photodiode or an avalanche photodiode. The avalanche photodiode may be a single photon avalanche diode (SPAD). In the present embodiment, in order to detect a weak signal at a single photon level at high speed, a SPAD that operates by Geiger driving is used for the light receiving element 40. The light receiving element 40 is driven by the light reception driving unit 30. When receiving a part of the laser pulse light from the light emitting element 20, the light receiving element 40 outputs a power supply switching signal of a low level or a high level to the power supply switching unit 60. The power supply switching signal of the low level is a signal for turning on the power supply switching unit 60, and the power supply switching signal of the high level is a signal for turning off the power supply switching unit 60.

The power generator 50 is a power supply circuit that supplies power to the light emitting element 20. The power generator 50 may be, for example, a linear regulator, a switching regulator, or the like. The power generator 50 supplies power to the light emitting element 20 via the power supply switching unit 60.

The power supply switching unit 60 switches a power supply voltage applied from the power generator 50 to the anode of the light emitting element 20 based on the power supply switching signal from the light receiving element 40. Here, the power supply voltage is a voltage corresponding to a voltage between the anode and the cathode. When the power supply switching signal of the low level is output from the light receiving element 40, the power supply switching unit 60 electrically connects the power generator 50 and the light emitting element 20 to enable power supply from the power generator 50 to the light emitting element 20. On the other hand, when the power supply switching signal of the high level is output from the light receiving element 40, the power supply switching unit 60 electrically disconnects the power generator 50 and the light emitting element 20 and disables power supply from the power generator 50 to the light emitting element 20.

The control unit 70 controls an entire operation of the light emitting device 1. The control unit 70 may be configured by a semiconductor integrated circuit such as FPGA (Field Programmable Gate Array), ASIC (Application Specific Integrated Circuit). The control unit 70, the light emission driving unit 10, the power generator 50, and the power supply switching unit 60 are examples of a power supply control unit that controls a power supply voltage applied to the light emitting element 20.

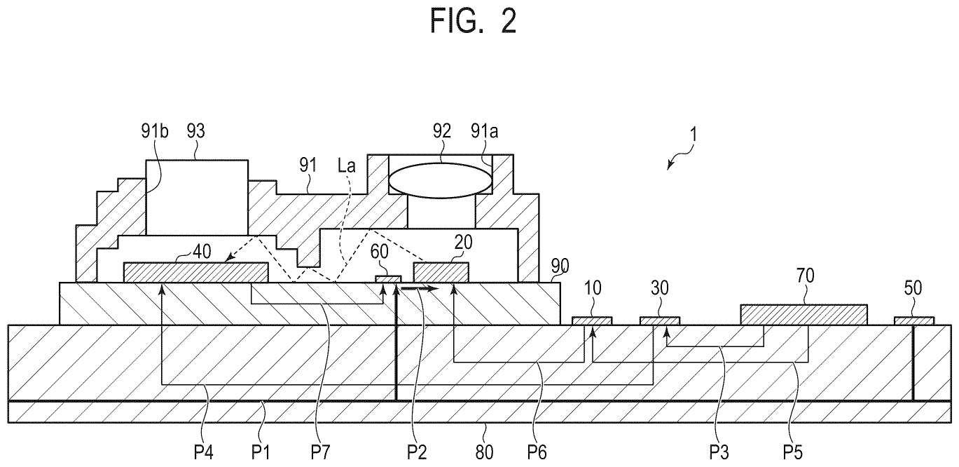

Next, the structure of the light emitting device 1 will be described. FIG. 2 is a cross-sectional view of the light emitting device 1. The light emission driving unit 10, the light reception driving unit 30, the power generator 50, the control unit 70, and the package substrate 90 are mounted on the printed circuit board 80 of the light emitting device 1. The light emitting element 20, the light receiving element 40, the power supply switching unit 60, and a housing (reflective member) 91 are mounted on the package substrate 90.

A plurality of paths P1 to P7 for transmitting various signals and power are formed on the printed circuit board 80 and the package substrate 90. Although the paths P1 to P7 may be constituted by metal wirings, via holes, connection terminals, and the like, the paths P1 to P7 are schematically illustrated in FIG. 2 and do not necessarily represent the positions of the metal wirings, the via holes, and the connection terminals.

The path P1 supplies the power supply voltage from the power generator 50 to the power supply switching unit 60. The path P2 supplies the power supply voltage from the power supply switching unit 60 to the anode of the light emitting element 20. The path P3 transmits a light reception start request signal from the control unit 70 to the light reception driving unit 30. The path P4 transmits a drive signal from the light reception driving unit 30 to the light receiving element 40. The path P5 transmits a light emission start request signal from the control unit 70 to the light emission driving unit 10. The path P6 transmits a driving signal from the light emission driving unit 10 to the cathode of the light emitting element 20. The path P7 transmits a power supply switching signal from the light receiving element 40 to the power supply switching unit 60.

Although the package substrate 90 is provided with the power supply switching unit 60 as a component different from the light emitting element 20, the power supply switching unit 60 may be incorporated in the light emitting element 20.

The housing 91 covers the light emitting element 20 and the light receiving element 40 while supporting the diffusion unit 92 and the filter 93. The housing 91 is formed of a light-shielding resin material or metal material. The housing 91 has an opening 91a on a light axis of the light emitting element 20, and the diffusion unit 92 is provided in the opening 91a. The housing 91 has an opening 91b above the light receiving element 40, and a filter 93 is provided in the opening 91b. The light emitting element 20 and the light receiving element 40 are provided in an internal space of the housing 91. Most of the laser pulse light from the light emitting element 20 passes through the diffusion unit 92 and is emitted to an outside of the housing 91. A part of the laser pulse light is reflected inside the housing 91 as a reference light La without passing through the diffusion unit 92 and enters the light receiving element 40. Note that a filter may be provided in a middle of a path of the reference light La, that is, between the light emitting element 20 and the light receiving element 40. The filter reduces light of heat rays (infrared rays) generated from the light emitting element 20 and external light entering through the diffusion unit 92.

The diffusion unit 92 diffuses light. The diffusion unit 92 is disposed to face the light emitting element 20 in the emission direction of the laser pulse light emitted from the light emitting element 20. The diffusion unit 92 includes a diffusion plate having a concavo-convex structure. The concavo-convex is formed with a length of about the wavelength of the laser pulse light. The diffusion unit 92 diffuses the laser pulse light emitted from the light emitting element 20 to the outside of the light emitting device 1. Note that a function such as a light-reducing filter that reduces external light may be applied to the diffusion unit 92.

The filter 93 is disposed to face the light receiving element 40. When the light emitting element 20 emits the laser pulse light, the filter 93 guides a light reflected by a subject to the light receiving element 40 and suppresses an entry of external light other than the laser pulse light. The filter 93 may be a bandpass filter that reduces light other than the wavelength of the laser pulse light from the light emitting element 20, or a light-reducing filter that reduces external light. In addition, the filter 93 may include a resin member or a metal member that completely blocks external light.

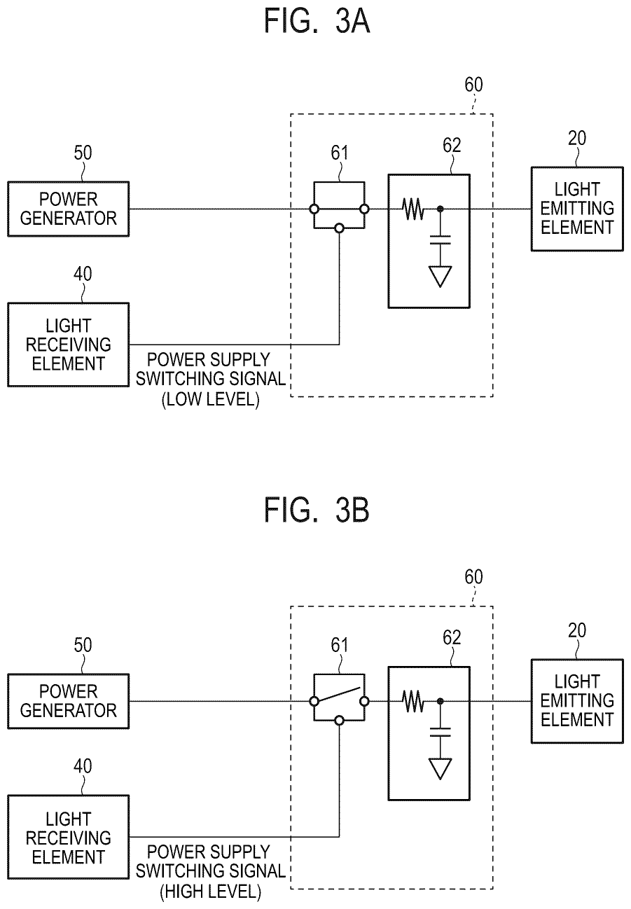

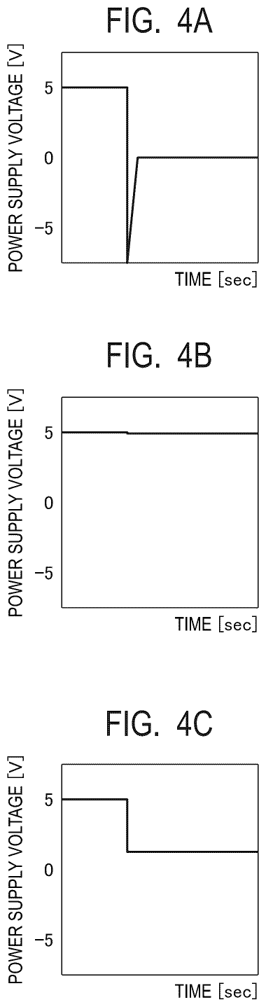

Next, the power supply switching unit 60 will be described in detail. FIG. 3A is a circuit diagram of the power supply switching unit 60, and a power supply path to the light emitting element 20 is connected. FIG. 3B is a circuit diagram of the power supply switching unit 60, and the power supply path to the light emitting element 20 is disconnected.

The power supply switching unit 60 includes a switch circuit 61 and a low-pass filter 62.

The switch circuit 61 includes a transistor and disconnects or conducts the power supply path to the light emitting element 20 in response to the power supply switching signal from the light receiving element 40. In the switch circuit 61, an input node is connected to the power generator 50, an output node is connected to the light emitting element 20 via the low-pass filter 62, and a control node is connected to the light receiving element 40. When the power supply switching signal of the low level is input from the light receiving element 40 to the control node, the switch circuit 61 is turned on, and the power supply voltage of a high level (e.g., 5 V) is supplied from the power generator 50 to the light emitting element 20 (see FIG. 3A). Here, when the drive signal of a low level (e.g., 0 V) is supplied to the cathode of the light emitting element 20, a current flows through the light emitting element 20, and the laser pulse light can be emitted from the light emitting element 20. A normal voltage (first power supply voltage) driving is to drive the light emitting element 20 while supplying the power supply voltage of the high level to the anode of the light emitting element 20.

As described above, when the light emitting element 20 emits the laser pulse light, a part of the laser pulse light enters the light receiving element 40 as the reference light La. Therefore, the power supply switching signal from the light receiving element 40 changes from the low level to the high level, and the switch circuit 61 is turned off. As a result, power is not supplied from the power generator 50 to the light emitting element 20, and a laser oscillation of the light emitting element 20 is stopped or suppressed (see FIG. 3B). A low voltage (second power supply voltage) driving is to block or suppress the power supplied to the anode of the light emitting element 20.

The low-pass filter 62 includes a resistor and a capacitor and is provided in a power supply path between the switch circuit 61 and the light emitting element 20. In the low-pass filter 62, one end of the resistor is connected to an output node of the switch circuit 61, and the other end of the resistor is connected to the anode of the light emitting element 20. A first electrode of the capacitor is connected to a connection node between the resistor and the light emitting element 20, and a second electrode of the capacitor is connected to ground. The low-pass filter 62 removes a signal having a frequency exceeding a cutoff frequency determined by a resistance of the resistor and a capacitance of the capacitor.

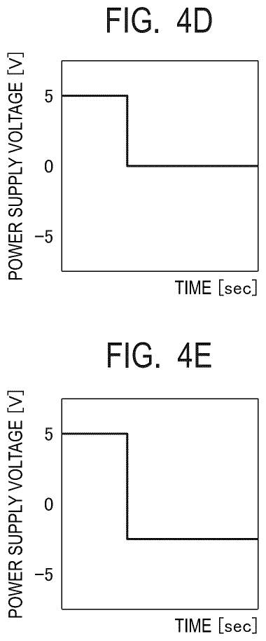

FIGS. 4A to 4E illustrate transient responses of the power supply voltage applied between the anode and cathode of the light emitting element 20 when the switch circuit 61 is turned off. Here, a waveform of the transient response is a simulation result obtained by modeling the light emitting element 20 using a rate equation. A full width at half maximum of the high peak value pulse light from the light emitting element 20 may be, for example, 0.1 nsec or less. Here, the full width at half maximum is a width of the waveform at a half height of a peak value of the high peak value pulse light. Here, the power supply voltage applied to the light emitting element 20 is set to 5 V, and the full width at half maximum of the high peak value pulse light is set to about 0.1 nsec.

FIG. 4A illustrates a transient response of the power supply voltage in a case where the low-pass filter 62 is not provided. Here, when the switch circuit 61 is turned off, an overshoot occurs, and the power supply voltage largely swings in a negative voltage direction. Overshoot may be caused by a power supply wiring, parasitic inductors. Overshoot may impair a function of a circuit element. A relationship between a time constant of the low-pass filter 62 and the transient response of the power supply voltage will be described below.

FIG. 4B illustrates a waveform of a transient response of the power supply voltage in the low-pass filter 62 (time constant τ=100 nsec) including a resistor of 100 mΩ and a capacitor of 1 uF. The time constant t of the low-pass filter 62 is large with respect to the full width at half maximum of the high peak value pulse light. Therefore, when the switch circuit 61 is turned off, the power supply voltage hardly decreases. As described above, it takes a long time until the power supply voltage of the light emitting element 20 becomes the off level, which makes it difficult to realize high-speed operation.

FIG. 4C illustrates a transient response of the power supply voltage in the low-pass filter 62 (time constant τ=0.05 nsec) including a resistor of 50 mΩ and a capacitor of 1 nF. In this case, the full width at half maximum of the high peak value pulse light is substantially equal to 2τ. Although there is no problem in the responsiveness of the power supply voltage, the capacitance of the capacitor is slightly large. Therefore, when the switch circuit 61 is turned off, the capacitor operates as a secondary power supply, and the power supply voltage swings in a positive direction. Since the power supply voltage when the switch circuit 61 is off is sufficiently smaller than the power supply voltage (5 V) when the switch circuit 61 is on, the steady oscillation light of the light emitting element 20 can be suppressed. In this case, since a difference between the power supply voltage when the switch circuit 61 is on and the power supply voltage when the switch circuit 61 is off is small, the time of the transient response of the power supply voltage can be shortened, and high-speed driving becomes possible. A threshold value of the power supply voltage may be determined by characteristics of the light emitting element 20.

FIG. 4D illustrates a transient response of the power supply voltage in the low-pass filter 62 (time constant τ=0.001 nsec) including a resistor of 10 mΩ and a capacitor of 0.1 nF. In this case, the full width at half maximum of the high peak value pulse light is substantially equal to 100τ. A time of the transient response of the power supply voltage is also early, and the power supply voltage when the switch circuit 61 is off is lowered to 0 V. This is used as the low-pass filter according to the present embodiment.

FIG. 4E illustrates a transient response of the power supply voltage in the low-pass filter 62 (time constant τ=0.05 psec) including a resistor of 5 mΩ and a capacitor of 0.01 nF. In this case, the full width at half maximum of the high peak value pulse light is substantially equal to 2000τ. Since the capacitance (=0.01 nF) is small, an overshoot occurs when the switch circuit 61 is turned off, and the power supply voltage swings in the negative direction. At this time, although the laser pulse light is not output from the light emitting element 20, since the negative power supply voltage is continuously applied to the anode of the light emitting element 20, a protection circuit may be necessary.

As illustrated in FIGS. 4A to 4E, in one embodiment, the resistance and the capacitance value of the low-pass filter 62 be appropriately set so as to have the transient response characteristics illustrated in FIG. 4C or FIG. 4D. For example, in one embodiment, the time constant τ is set so that the full width at half maximum of the high peak value pulse light is 2τ or more and 100τ or less. By providing the low-pass filter 62 having an appropriate time constant, it is possible to reduce overshoot and protect the circuit element. In addition, a slew rate of the transient response can be improved, and high-speed driving can be expected.

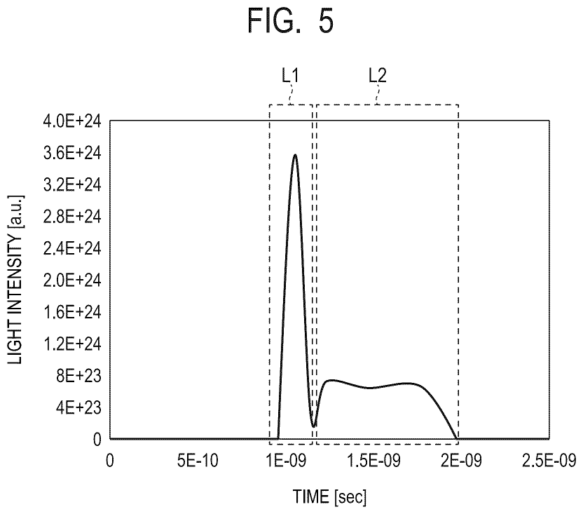

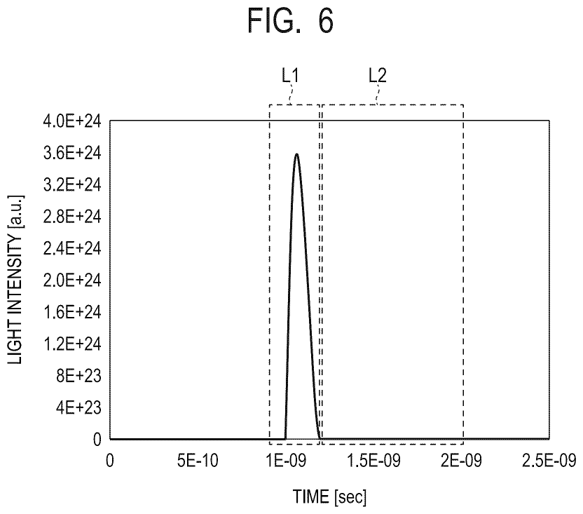

Next, the waveform of the laser pulse light will be described with reference to FIGS. 5 and 6. In FIGS. 5 and 6, a horizontal axis represents time, and a vertical axis represents a light intensity of the laser pulse light.

FIG. 5 illustrates a laser pulse light according to a comparative example. In FIG. 5, the low voltage drive is not performed, and the laser pulse light is emitted by the normal voltage drive. Since the light emitting element 20 is driven at the normal voltage, the high peak value pulse light L1 is followed by the steady oscillation light L2. The steady oscillation light L2 has a light intensity smaller than the light intensity of the high peak value pulse light L1.

FIG. 6 illustrates the laser pulse light according to the present embodiment. In FIG. 6, the laser pulse light is emitted by both the normal voltage driving and the low voltage driving. That is, the normal voltage driving is switched to the low voltage driving immediately after the high peak value pulse light L1 is emitted by the normal voltage driving. Accordingly, the emission of the steady oscillation light L2 can be suppressed. Although the light intensity of the high peak value pulse light L1 of the laser pulse light according to the present embodiment is the same as the light intensity of the high peak value pulse light L1 of the comparative example. On the other hand, the light intensity of the steady oscillation light L2 of the present embodiment is smaller than the light intensity of the steady oscillation light L2 of the comparative example. In FIG. 6, the steady oscillation light L2 is suppressed until the steady oscillation light L2 is substantially not output.

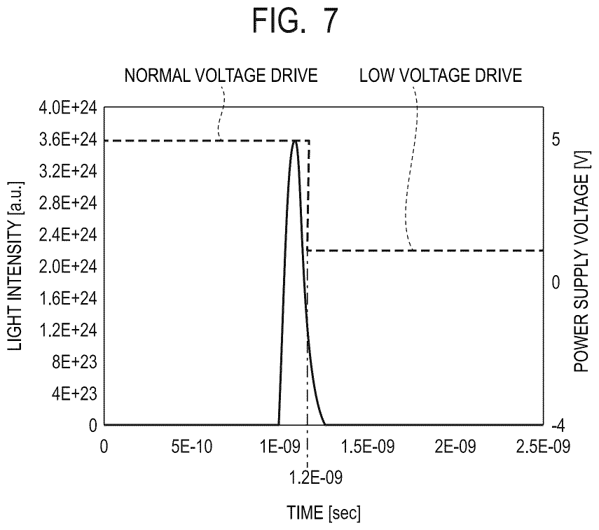

FIG. 7 is a diagram illustrating a relationship between a waveform of a laser pulse light and a power supply voltage according to the present embodiment. The power supply voltage represents a voltage at the anode of the light emitting element 20. In FIG. 7, a horizontal axis represents time, a vertical axis on the left side represents the light intensity of the laser pulse light, and a vertical axis on the right side represents the power supply voltage. In FIG. 7, the power supply voltage applied to the light emitting element 20 is illustrated by a dotted line when the resistor and the capacitor of the low-pass filter 62 are configured under the condition illustrated in FIG. 4C. In FIG. 7, the normal voltage driving is switched to the low voltage driving in accordance with the emission start timing of the steady oscillation light (time 1.2 nsec). The voltage at the time of normal voltage driving is about 5 V, and the voltage at the time of low voltage driving is about 1.2 V. The emission of the steady oscillation light is suppressed by switching to the low voltage driving.

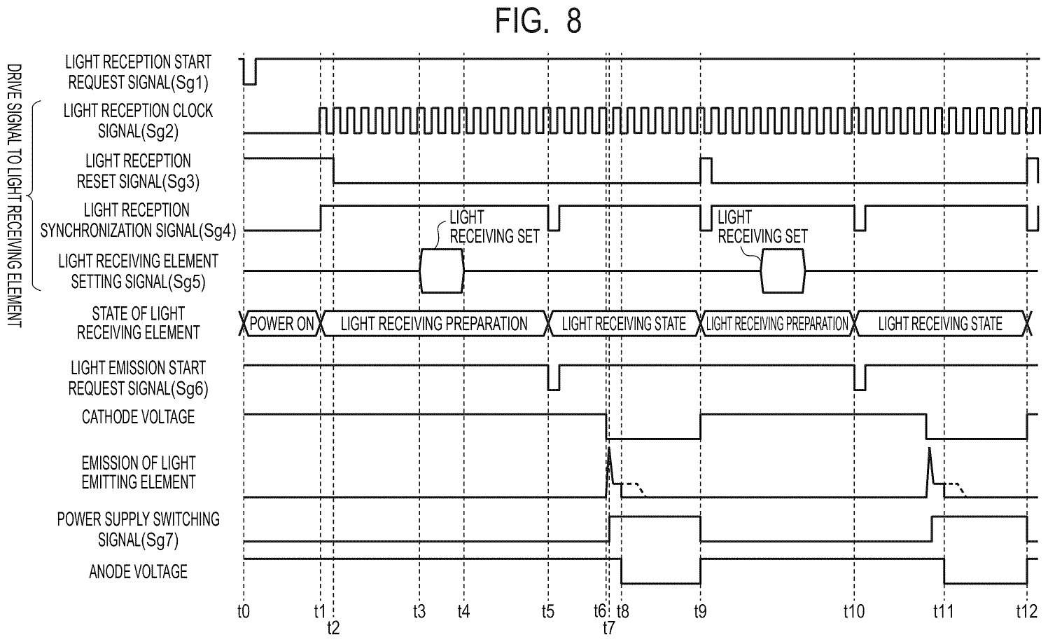

Next, an operation of the light emitting device 1 will be described. FIG. 8 is a time chart illustrating the operation of the light emitting device 1.

At time t0, the control unit 70 receives a trigger signal from an outside of the light emitting device 1 and outputs a light reception start request signal Sg1 to the light reception driving unit 30. When receiving the light reception start request signal Sg1, the light reception driving unit 30 starts supplying power to the light receiving element 40. At this time, in order to suppress malfunction or the like due to mixing of external noise, the light reception driving unit 30 outputs a light receiving reset signal Sg3 to the light receiving element 40 and maintains a reset state of the light receiving element 40. The period of the reset state (time t0 to t1) is, for example, a time (for example, 100 msec) until the power supply voltage supplied to the light receiving element 40 becomes stable. However, since a type of a necessary power supply voltage differs depending on the light receiving element 40, it may take time to stabilize all the power supply voltages supplied to the light receiving element 40. Therefore, the period of the reset state is not limited to 100 msec.

On the other hand, the control unit 70 turns on the switch circuit 61 in the power supply switching unit 60, and the power supply switching unit 60 starts supplying the power supply voltage of the high level to the anode of the light emitting element 20 (normal voltage driving). At this time, the cathode voltage of the light emitting element 20 is maintained at the high level, no current provides the light emitting element 20, and the light emitting element 20 stops laser oscillation.

At time t1, the light reception driving unit 30 supplies a light reception clock signal Sg2 serving as a reference of an operation timing to the light receiving element 40. In addition, the light reception driving unit 30 changes a light reception synchronization signal Sg4 from a low level to a high level and starts a preparation for light reception in the light receiving element 40. In this light reception preparation, a light reception has not yet started.

At time t2, the light reception driving unit 30 changes the light receiving reset signal Sg3 of the light receiving element 40 from the high level to the low level and cancels the reset state of the light receiving element 40.

From time t3 to time t4, the light reception driving unit 30 outputs a light receiving element setting signal Sg5 to the light receiving element 40. The light receiving element setting signal Sg5 represents an operation setting of the light receiving element 4. The light receiving element setting signal Sg5 is written to a register by an I2C (Inter-Integrated Circuit) or a three-wire or four-wire serial communication method.

At time t5, the light reception driving unit 30 changes the light reception synchronization signal Sg4 from the high level to the low level. In response to the light reception synchronization signal Sg4 of the low level, the light receiving element 40 is set based on the light element setting signal Sg5, and the light receiving element 40 changes from the light reception preparation state to the light reception state. At the same time, the control unit 70 outputs a light emission start request signal Sg6 to the light emission driving unit 10.

At time t6, the light emission driving unit 10 receives the light emission start request signal Sg6 and changes the cathode voltage of the light emitting element 20 from the high level to the low level. As a result, a drive current flows through the light emitting element 20, and the laser pulse light is emitted from the light emitting element 20. A part of the laser pulse light emitted from the light emitting element 20 enters the light receiving element 40 as the reference light La.

At time t7, when the light receiving element 40 detects the reference light La, a power supply switching signal Sg7 is changed from the low level to the high level.

At time t8, the power supply switching unit 60 changes the switch circuit 61 from on to off in response to the power supply switching signal Sg7 of the high level and changes the anode voltage from the high level to the low level (low voltage driving). Accordingly, the drive current of the light emitting element 20 is blocked, and the emission of the steady oscillation light L2 in the light emitting element 20 is stopped or suppressed.

At time t9, the light reception driving unit 30 changes the light receiving synchronization signal Sg4 from the high level to the low level and changes the light receiving element 40 from the light receiving state to the light receiving preparation state. At this time, the light reception driving unit 30 outputs the light receiving reset signal Sg3 to the light receiving element 40 to reset the light receiving element 40. When reset, the light receiving element 40 changes the power supply switching signal Sg7 from the high level to the low level.

At time t9, when receiving the power supply switching signal Sg7 of the low level from the light receiving element 40, the power supply switching unit 60 changes the anode voltage of the light emitting element 20 from the low level to the high level (normal voltage driving). At this time, the cathode voltage of the light emitting element 20 changes from the low level to the high level, no current provides the light emitting element 20, and the light emitting element 20 stops laser oscillation.

The operation from time t9 to time t12 is the same as the operation from time t1 to time t9. Since there is a preparation period for the light receiving element 40, in one embodiment, the period of the light emission start request signal Sg6 is set to be two or more times the period of the light reception synchronization signal Sg4.

As described above, according to the light emitting device 1 of the present embodiment, the high peak value pulse light L1 is emitted from the light emitting element 20 by controlling the power supply voltage to the normal voltage, and then the power supply voltage is controlled to the low voltage lower than the normal voltage in accordance with the power supply switching signal Sg7. Specifically, the light emission driving unit 10 causes the high peak value pulse light L1 to be emitted by changing the cathode voltage of the light emitting element 20 from the high level to the low level. Thereafter, the power supply switching unit 60 controls the anode voltage of the light emitting element 20 to the low voltage by changing from the high level to the low level in accordance with the power supply switching signal Sg7. In this way, the power supply switching unit 60 disconnects the power supply path to the light emitting element 20 according to the power supply switching signal Sg7 and controls the anode voltage to the low voltage.

Accordingly, the light emitting device 1 easily suppresses the emission of the undesired light (steady oscillation light L2). Therefore, the light emitting device 1 can reduce power consumption while maintaining the output of the high peak value pulse light L1. For example, in a case where the light emitting device 1 is applied to a ranging device, the power supply of the ranging device can be improved by distributing a reduction in power consumption to other devices constituting the ranging device. Even if the steady oscillation light L2 having a small contribution to the distance measurement operation is suppressed, an influence on the distance measurement operation is small. In addition, the light emitting device 1 controls the cathode voltage when the light emitting element 20 emits light and controls the anode voltage when the light emitting element 20 stops emitting light. Therefore, the light emitting device 1 can accurately emit short pulses as compared with a case where the cathode voltage is controlled as in the related art.

### Second Embodiment

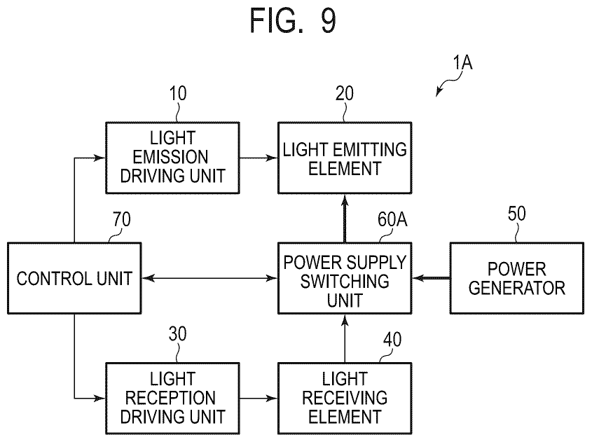

Next, a second embodiment will be described. FIG. 9 is a block diagram of a light emitting device 1A according to the present embodiment.

The present embodiment differs from the first embodiment in that a time constant of a low-pass filter 62A is variable. In the present embodiment, the same components as those in the first embodiment are denoted by the same reference numerals, and detailed description thereof will be appropriately omitted.

The light emitting device 1A has the same configuration as the light emitting device 1 according to the first embodiment except for a control by the control unit 70 and a circuit configuration of a power supply switching unit 60A.

The control unit 70 is connected to the power supply switching unit 60A, and outputs an RC control signal for changing the time constant of the low-pass filter 62A of the power supply switching unit 60A to the power supply switching unit 60A. Note that the control unit 70 and the power supply switching unit 60A can communicate with each other by a method such as I2C or SPI (Serial Peripheral Interface).

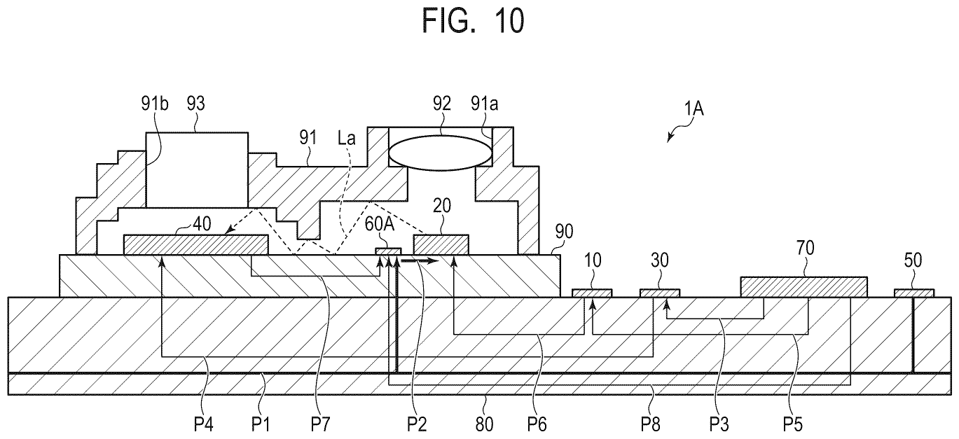

FIG. 10 is a cross-sectional view of the light emitting device 1A. The light emitting device 1A has the same configuration as the light emitting device 1 according to the first embodiment except that a path P8 is further provided in addition to the paths P1 to P7. Although the path P8 may include a metal wiring, a via hole, a connection terminal, and the like, the path P8 is schematically illustrated in FIG. 10 and does not necessarily represent the positions of the metal wiring, the via hole, and the connection terminal. The path P8 transmits the RC control signal from the control unit 70 to the power supply switching unit 60A.

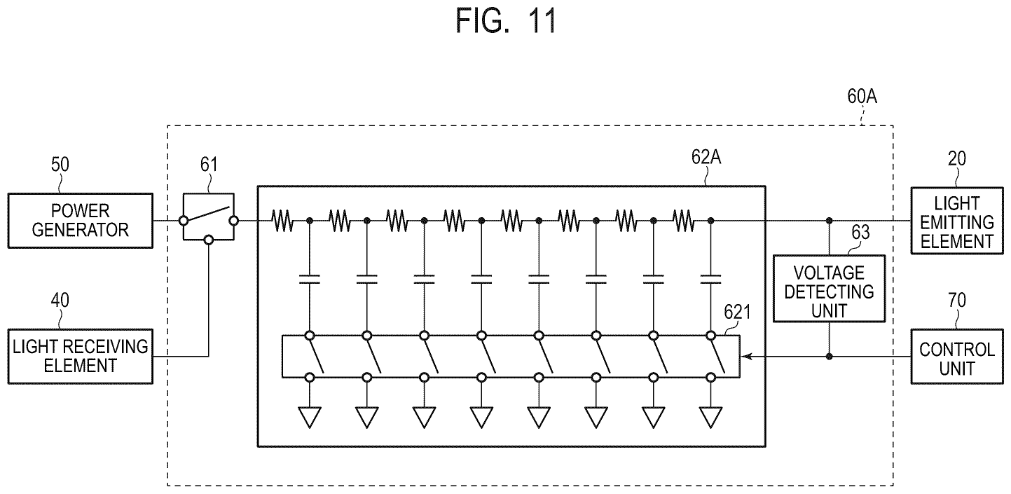

FIG. 11 is a circuit diagram of the power supply switching unit 60A. The power supply switching unit 60A includes a switch circuit 61, a low-pass filter 62A, and a voltage detecting unit 63.

The switch circuit 61 includes a transistor and disconnects or connects a power supply path to the light emitting element 20 according to the power supply switching signal Sg7 from the light receiving element 40. In the switch circuit 61, an input node is connected to the power generator 50, an output node is connected to the light emitting element 20 via the low-pass filter 62A, and a control node is connected to the light receiving element 40.

The low-pass filter 62A includes N numbers of resistors, N numbers of capacitors, and a switch unit 621. The switch unit 621 includes N numbers of capacitive switches. Here, “N” is a natural number. The N numbers of resistors are connected in series between an input node of the switch circuit side and an output node of the light emitting element side. The first electrodes of the N numbers of capacitors are connected to (N−1) numbers of connection nodes and the output node of the N numbers of resistors, respectively. The N numbers of capacitive switches are respectively connected between second electrodes of the N numbers of capacitors and ground. The low-pass filter 62A can control each capacitance switch to be turned on or off based on the RC control signal from the control unit 70. The second electrode of the capacitor is connected to the ground by turning on the capacitive switch, and the second electrode of the capacitor is not connected to the ground by turning off the capacitive switch. By turning on or off each capacitance switch, the time constant of the low-pass filter 62A can be dynamically changed. The low-pass filter 62A removes a signal having a frequency exceeding a cutoff frequency determined by a time constant.

The voltage detecting unit 63 detects a power supply voltage applied to the light emitting element 20. The voltage detecting unit 63 is connected to the control unit 70, and outputs the detected power supply voltage to the control unit 70.

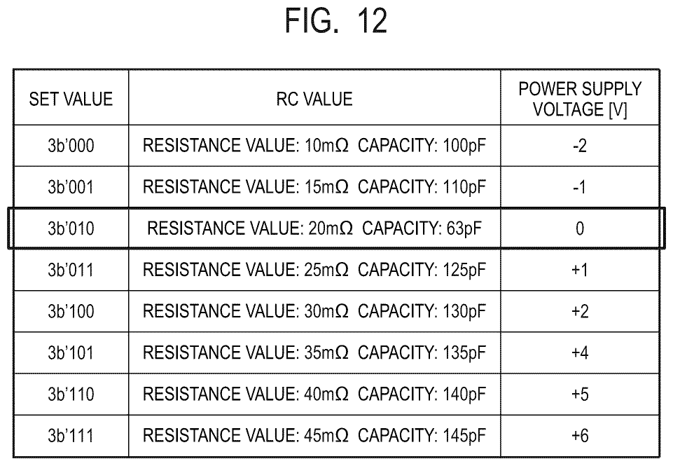

FIG. 12 is a diagram summarizing the results of switching the switch circuit 61 from on to off for each time constant determined by the combination (RC value) of the resistance and the capacitance in the low-pass filter 62A and reading the power supply voltage at that time from the voltage detecting unit 63. In FIG. 12, a set value representing a combination of the resistance and the capacitance is represented by three bits (“000” to “111”). Here, the power supply voltage is “0 V” when the switch circuit 61 is turned off in a state where the low-pass filter 62 A is set to the time constant determined by the RC value (resistance=20 mΩ, capacitance=120 pF) represented by the set value “010”. Therefore, the time constant determined by this RC value is suitable. In one embodiment, the time constant of the low-pass filter 62A is executed at a timing before light reception is started, for example, in a light reception preparation period from time t1 to time t5 in FIG. 8.

The transient response of the power supply voltage when the switch circuit 61 is turned off may be different from a design value due to manufacturing variations, power supply voltage variations, changes in ambient temperature, and the like. According to the present embodiment, since the time constant of the low-pass filter 62A is variable, it is possible to suppress the influence of the above-described variation or the like. Accordingly, the light emitting device 1A can reduce the variation in the transient response of the power supply voltage when the switch circuit 61 is turned off and can accurately suppress the steady oscillation light. However, compared to the light emitting device 1 of the first embodiment, the light emitting device 1A of the present embodiment has a larger number of components, and it is necessary to add a process of readjusting the time constant. Therefore, in an evaluation when using the light emitting device, it is conceivable to use the light emitting device 1 of the first embodiment if the influence of various variations is within an assumed range, and to use the light emitting device 1A of the second embodiment if the influence of various variations is outside the assumed range.

### Third Embodiment

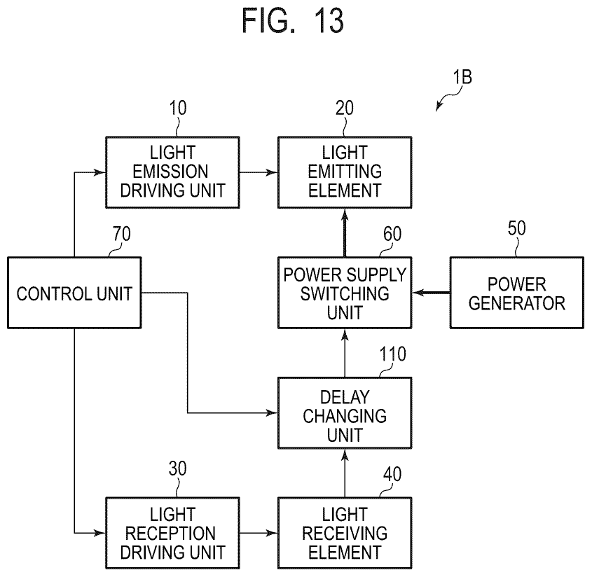

Next, a third embodiment will be described. FIG. 13 is a block diagram of a light emitting device 1B according to the present embodiment.

The light emitting device 1B of the present embodiment is different from the light emitting devices 1 and 1A of the other embodiments in that a delay changing unit 110 that changes a delay of the power supply switching signal Sg7 from the light receiving element 40 is provided. In the present embodiment, the same components as those of the other embodiments are denoted by the same reference numerals, and detailed description thereof will be appropriately omitted.

The light emitting device 1B has the same configuration as that of the light emitting device 1 according to the first embodiment except that the control by the control unit 70 and the delay changing unit 110 are provided.

Variations in delay of the power supply switching signal Sg7 may occur between the light receiving element 40 and the power supply switching unit 60 due to manufacturing variations, variations in power supply voltage, changes in ambient temperature, and the like. If the delay of the power supply switching signal Sg7 swings, there may be a discrepancy between the emission start timing of the steady oscillation light and the switching timing to the low voltage, and the steady oscillation light L2 may not be appropriately suppressed. Therefore, the light emitting device 1B includes the delay changing unit 110 that changes the delay of the power supply switching signal Sg7.

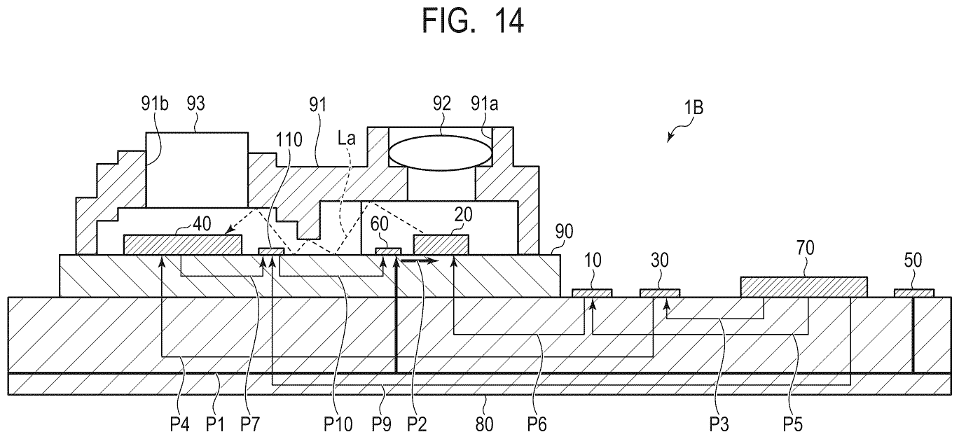

FIG. 14 is a cross-sectional view of the light emitting device 1B. The light emitting device 1B has the same configuration as that of the light emitting device 1 according to the first embodiment except that paths P9 and P10 are further provided in addition to the paths P1 to P6, a connection destination of the path P7 is different, and the delay changing unit 110 is provided. The delay changing unit 110 is provided on the package substrate 90. The paths P7, P9, and P10 may be including a metal wiring, a via hole, a connection terminal, and the like, but these paths are schematically illustrated in FIG. 14, and do not necessarily represent the positions of the metal wiring, the via hole, and the connection terminal.

The path P9 transmits a control signal from the control unit 70 to the delay changing unit 110. The path P7 transmits the power supply switching signal Sg7 from the light receiving element 40 to the delay changing unit 110. The path P10 transmits the power supply switching signal Sg7 from the delay changing unit 110 to the power supply switching unit 60.

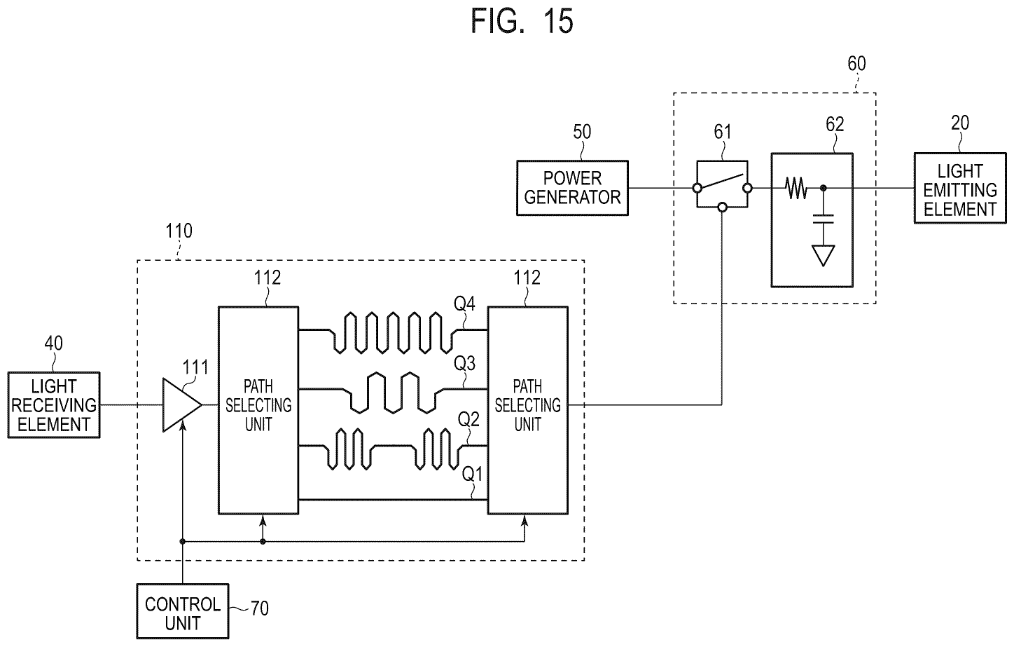

FIG. 15 is a block diagram of the delay changing unit 110. The delay changing unit 110 changes the delay time of the power supply switching signal Sg7 from the light receiving element 40, and includes a buffer circuit 111, paths Q1 to Q4, and path selecting units (selecting circuits) 112.

The delay changing unit 110 can change a drive current (output impedance) and a signal path of the power supply switching signal Sg7 based on the control signal from the control unit 70.

The drive current of the buffer circuit 111 can be changed. For example, the drive current can be appropriately changed to any of 4 mA, 8 mA, and 10 mA, and “through”. Here, “through” means that the power supply switching signal Sg7 is output without passing through the buffer circuit 111. The output node of the buffer circuit 111 is connected to the paths Q1 to Q4 via the path selecting units 112.

The paths Q1 to Q4 are metal wirings capable of transmitting the power supply switching signal Sg7. The paths Q1 to Q4 are provided between the path selecting units 112. The paths Q1 to Q4 are formed to have lengths different from each other. Here, the path Q1 is formed in a straight line, and a part of the paths Q2 to Q4 is formed to meander so that the paths Q2 to Q4 having different lengths are configured. The signal delay can be changed by selecting one of the paths Q1 to Q4.

The path selecting units 112 select one of the paths Q1 to Q4 based on a control signal from the control unit 70. The path selecting units 112 are provided on both sides of the paths Q1 to Q4. Each path selecting unit 112 includes, for example, a switch circuit. The switch circuit of one path selecting unit 112 connects the buffer circuit 111 to one of the paths Q1 to Q4. The switch circuit of the other path selecting unit 112 connects the power supply switching unit 60 to one of the paths Q1 to Q4. For example, when the buffer circuit 111 and the path Q1 are connected to each other and the power supply switching unit 60 and the path Q1 are connected to each other, the power supply switching signal Sg7 is transmitted from the buffer circuit 111 to the power supply switching unit 60 via the path Q1.

The control unit 70 can change the drive current of the delay changing unit 110 by sending a control signal to the buffer circuit 111. In addition, the control unit 70 sends a control signal to the path selecting unit 112, selects one of the paths Q1 to Q4, and can change the delay time of the power supply switching signal Sg7.

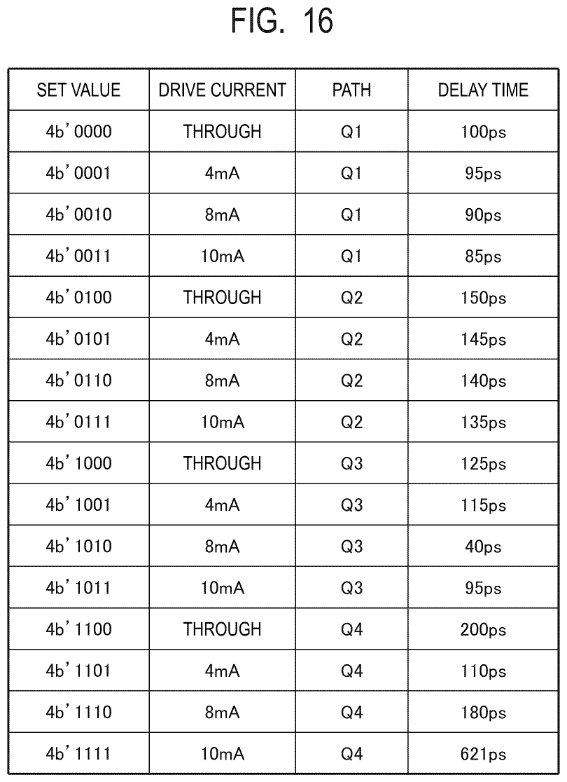

FIG. 16 is a diagram illustrating a relationship between a drive current, a path, and a delay time. In FIG. 16, four types of drive currents (4 mA, 8 mA, 10 mA, and “through”) and four paths Q1 to Q4 are illustrated, and delay times of 16 patterns are illustrated. The delay times of the 16 patterns can be calculated in advance. In FIG. 16, the set value representing the delay times of 16 patterns is represented by 4 bits (“0000” to “1111”). For example, in the case of a condition of the drive current “through” and the path “Q1” represented by the set value “0000”, the delay time is “100 ps”. Here, by specifying the set value illustrated in FIG. 16, the condition of the drive current and the path is set from the control unit 70, and a suitable delay time is found from a state of the waveform of the laser pulse light of the light emitting element 20 under the condition.

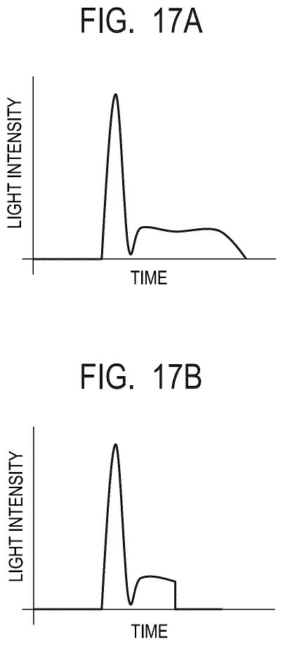

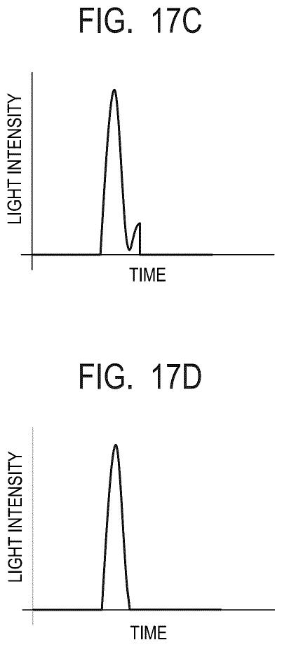

FIGS. 17A to 17D are diagrams of waveforms of the laser pulse light according to the delay time.

FIG. 17A is a diagram of the waveform of the laser pulse light when the switching to the low voltage is significantly delayed because the delay time is too long. In this case, since the switching timing to the low voltage and the emission start timing of the steady oscillation light are significantly different from each other, the waveform in which the steady oscillation light cannot be suppressed is represented.

FIG. 17B is a waveform diagram of the laser pulse light when the switching to the low voltage is slightly delayed because the delay time is slightly long. In this case, since the switching timing to the low voltage and the emission start timing of the steady oscillation light are slightly different from each other, the steady oscillation light is not suppressed by about half.

FIG. 17C is a waveform diagram of the laser pulse light when the switching to the low voltage is slightly delayed because the delay time is slightly long. In this case, since the switching timing to the low voltage and the emission start timing of the steady oscillation light are slightly different from each other, the steady oscillation light is not suppressed to some extent.

FIG. 17D is a waveform diagram when the delay time is appropriate and the switching timing to the low voltage and the emission start timing of the steady oscillation light coincide with each other. In this case, since the switching timing to the low voltage and the emission start timing of the steady oscillation light coincide with each other, a waveform in which the steady oscillation light can be suppressed is represented.

In this way, the set values indicating the drive current and the path illustrated in FIG. 16 are set by the control unit 70, and a suitable delay time is found from the state of the waveform of the laser pulse light of the light emitting element 20 (here, the waveform of the laser pulse light in FIG. 17D). Then, the drive current and the path corresponding to the suitable delay time are set in advance.

Thus, even when the delay of the power supply switching signal Sg7 varies due to various variations, the delay of the power supply switching signal Sg7 is changed by the delay changing unit 110, so that the timing of switching to the low voltage can coincide with the timing of starting emission of the steady oscillation light. Accordingly, the steady oscillation light can be suppressed with high accuracy, and thus power consumption can be effectively reduced. However, compared to the light emitting device 1 of the first embodiment, the light emitting device 1B of the present embodiment has a larger number of components, and it is necessary to add a process of adjusting the delay time. Therefore, in an evaluation when using the light emitting device, it is conceivable to use the light emitting device 1 of the first embodiment if the influence of various variations is within an assumed range, and to use the light emitting device 1B of the third embodiment if the influence of various variations is outside the assumed range.

### Fourth Embodiment

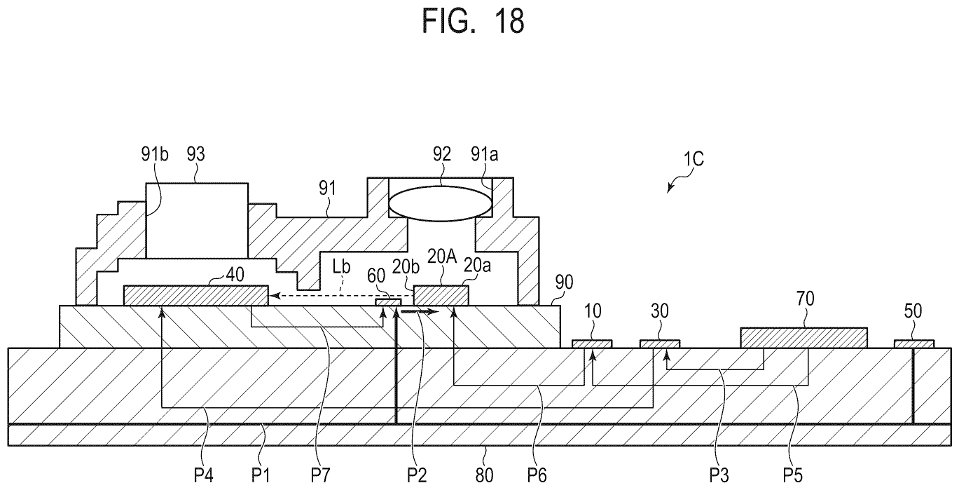

Next, a fourth embodiment will be described. FIG. 18 is a cross-sectional view of a light emitting device 1C according to the present embodiment.

The light emitting device 1C according to the present embodiment is different from the light emitting device 1 according to the first embodiment in that the power supply switching unit 60 is switched after a spontaneous emission light Lb emitted from a side surface of a light emitting element 20A is detected.

The light emitting element 20A has a first emission surface 20a and a second emission surface 20b. The first emission surface 20a is an emission surface that emits the laser pulse light toward the diffusion unit 92. In other words, the first emission surface 20a is an emission surface that emits the laser pulse light in a normal direction of the printed circuit board 80.

The second emission surface 20b is an emission surface different from the first emission surface 20a and is an emission surface that emits a part of the laser pulse light (natural emission light Lb) toward the light receiving element 40. In other words, the second emission surface 20b is an emission surface that emits the spontaneous emission light Lb in a direction intersecting the normal direction of the printed circuit board 80.

A part of the laser pulse light emitted from the second emission surface 20b of the light emitting element 20A is incident on the light receiving element 40 as the spontaneous emission light Lb. After detecting the spontaneous emission light Lb, the light receiving element 40 changes the power supply switching signal Sg7 from the low level to the high level, and outputs the power supply switching signal Sg7 of the high level to the power supply switching unit 60. In addition, the spontaneous emission light Lb may leak and be emitted before the high peak value pulse light is emitted. Therefore, in the light emitting device 1C of the present embodiment, the delay time of the power supply switching signal Sg7 needs to be longer than that in the case of the other embodiments.

### Fifth Embodiment

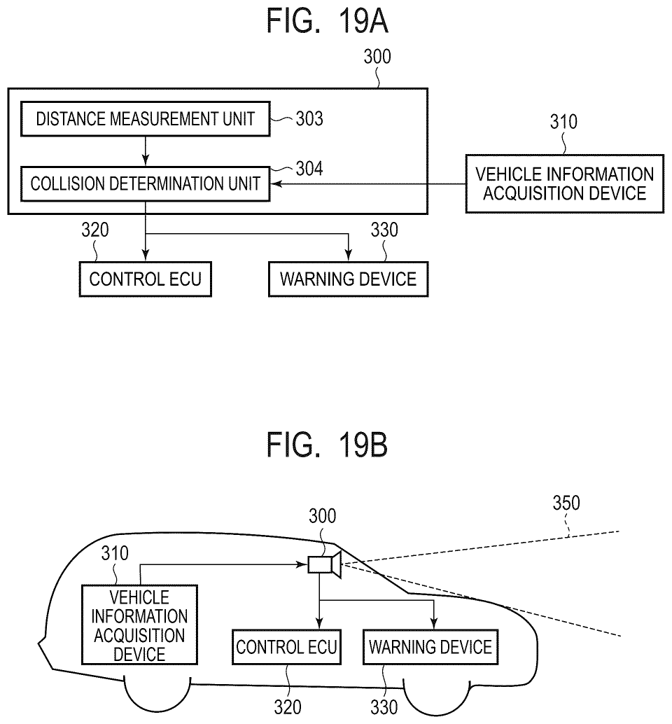

Next, a movable body according to the fifth embodiment will be described with reference to FIGS. 19A and 19B. FIGS. 19A and 19B are diagrams illustrating the movable body according to the fifth embodiment.

FIG. 19A illustrates a configuration example of a device mounted on a vehicle as an in-vehicle camera. A device 300 includes a distance measurement unit 303 that measures a distance to an object, and a collision determination unit 304 that determines whether there is a possibility of collision based on the distance measured by the distance measurement unit 303. The distance measurement unit 303 includes the light emitting device described in the first to fourth embodiments and a distance information acquisition unit. The distance information acquisition unit acquires information on a distance to the object based on a time difference between a timing at which the light is emitted from the light emitting element and a timing at which the light receiving element receives light emitted from the light emitting element and reflected by the object.

The device 300 is connected to a vehicle information acquisition device 310 and can acquire vehicle information such as a vehicle speed, a yaw rate, and a steering angle. In addition, a control ECU 320, which is a control device that outputs a control signal for generating a braking force to the vehicle based on the determination result of the collision determination unit 304, is connected to the device 300. The device 300 is also connected to a warning device 330 that issues a warning to the driver based on the determination result of the collision determination unit 304. For example, when the determination result of the collision determination unit 304 indicates that a possibility of collision is high, the control ECU 320 performs a vehicle control to avoid collision and reduce damage by applying a brake, returning an accelerator, suppressing engine output, or the like. The warning device 330 gives a warning to the user by sounding a warning such as a sound, displaying warning information on a screen of a car navigation system or the like, giving vibration to a seat belt or a steering wheel, or the like. These devices of the device 300 function as a movable body control unit that controls the operation of controlling the vehicle as described above.

In the present embodiment, the distance to the surroundings of the vehicle, for example, a front or a rear is measured by the device 300. FIG. 19B illustrates a device in the case of distance measurement in front of the vehicle (distance measurement range 350). The vehicle information acquisition device 310 serving as the distance measurement control unit sends an instruction to the device 300 or the distance measurement unit 303 to perform the distance measurement operation. With such a configuration, the accuracy of distance measurement can be further improved.

In the above description, an example in which control is performed so as not to collide with another vehicle has been described, but the aspect of the embodiments is also applicable to a control in which automatic driving is performed to follow another vehicle, a control in which automatic driving is performed so as not to protrude from a lane, and the like. Furthermore, the device is not limited to vehicles such as automobiles, and can be applied to, for example, ships, aircrafts, artificial satellites, industrial robots, consumer robots, and the like movable body (mobile devices). In addition, the aspect of the embodiments is not limited to the movable body and can be widely applied to devices utilizing object recognition or biological recognition, such as an intelligent traffic system (ITS) and a monitoring system.

### Sixth Embodiment

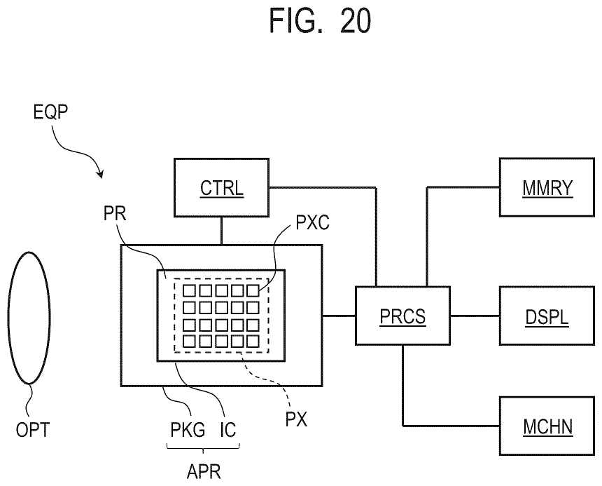

An equipment according to a sixth embodiment of the disclosure will be described with reference to FIG. 20. FIG. 20 is a block diagram of an equipment EQP according to the present embodiment.

The equipment EQP includes the light emitting device according to any of the first to fourth embodiments, and a photoelectric conversion device APR that converts a light signal emitted from a light emitting element of the light emitting device and reflected by an object into an electrical signal. All or part of the photoelectric conversion device APR is a semiconductor device IC. The photoelectric conversion device APR of the present example can be used as, for example, an image sensor, an AF (Auto Focus) sensor, a photometric sensor, or a distance measuring sensor. The semiconductor device IC has a pixel area PX in which pixel circuits PXC including photoelectric conversion units are arranged in a matrix. The semiconductor device IC may have a peripheral area PR around the pixel area PX. A circuit other than the pixel circuit can be disposed in the peripheral area PR.

The photoelectric conversion device APR may have a structure (chip stacked structure) in which a first semiconductor chip provided with a plurality of photoelectric conversion units and a second semiconductor chip provided with a peripheral circuit are stacked. Each of the peripheral circuits in the second semiconductor chip may be a column circuit corresponding to a pixel column of the first semiconductor chip. The peripheral circuits in the second semiconductor chip may be matrix circuits corresponding to pixels or pixel blocks in the first semiconductor chip. As the connection between the first semiconductor chip and the second semiconductor chip, a through electrode (TSV), an inter-chip wiring by direct bonding of a conductor such as copper, a connection by a micro bump between chips, a connection by wire bonding, or the like can be used.

The photoelectric conversion device APR may include a package PKG that accommodates the semiconductor device IC in addition to the semiconductor device IC. The package PKG can include a base to which the semiconductor device IC is fixed, a lid such as glass facing the semiconductor device IC, and a connection member such as a bonding wire or a bump for connecting a terminal provided in the base and a terminal provided in the semiconductor device IC.

The equipment EQP may further include at least one of a light device OPT, a control device CTRL, a processing device PRCS, a display device DSPL, a storage device MMRY, and a mechanical device MCHN. The light device OPT corresponds to the photoelectric conversion device APR and is, for example, a lens, a shutter, or a mirror. The control device CTRL controls the photoelectric conversion device APR, and is, for example, a semiconductor device such as an ASIC. The processing device PRCS processes a signal output from the photoelectric conversion device APR and constitutes an analog front end (AFE) or a digital front end (DFE). The processing unit PRCS is a semiconductor device such as a central processing unit (CPU) or an application specific integrated circuit (ASIC). The display device DSPL is an EL display device or a liquid crystal display device that displays information (image) obtained by the photoelectric conversion device APR. The storage device MMRY is a magnetic device or a semiconductor device that stores information (image) obtained by the photoelectric conversion device APR. The storage device MMRY is a volatile memory such as an SRAM or a DRAM, or a nonvolatile memory such as a flash memory or a hard disk drive. The mechanical device MCHN includes a movable portion or a propulsion portion such as a motor or an engine. In the equipment EQP, a signal output from the photoelectric conversion device APR is displayed on the display device DSPL or transmitted to the outside by a communication device (not illustrated) included in the equipment EQP. Therefore, in one embodiment, the equipment EQP further includes a storage device MMRY and a processing device PRCS separately from the storage circuit unit and the arithmetic circuit unit included in the photoelectric conversion device APR.

The equipment EQP illustrated in FIG. 20 can be an electronic device such as an information terminal (for example, a smartphone or a wearable terminal) or a camera (for example, an interchangeable lens camera, a compact camera, a video camera, and a monitoring camera) having a photographing function. The mechanical device MCHN in the camera can drive components of the light device OPT for zooming, focusing, and shutter operation. The equipment EQP may be a vehicle, a ship, or a transportation device (movable body) such as flying object. The equipment EQP may be a medical device such as an endoscope or a CT scanner.

The mechanical device MCHN in the transport device can be used as a mobile device. The equipment EQP as a transport device is suitable for transporting the photoelectric conversion device APR and assisting and/or automating operation (manipulation) by an imaging function. The processing device PRCS for assisting and/or automating driving (manipulation) can perform processing for operating the mechanical device MCHN as a moving device based on information obtained by the photoelectric conversion device APR.

The photoelectric conversion device APR according to the present embodiment can provide a high value to a designer, a manufacturer, a seller, a purchaser, and/or a user thereof. Therefore, when the photoelectric conversion device APR is mounted on the equipment EQP, the value of the equipment EQP can also be increased. Therefore, in manufacturing and selling the equipment EQP, it is advantageous to determine the mounting of the photoelectric conversion device APR to the present embodiment on the equipment EQP in order to increase the value of the equipment EQP.

### Modified Embodiments

The disclosure is not limited to the above-described embodiment, and various modifications are possible. For example, an example in which a part of the configuration of any of the embodiments is added to another embodiment or an example in which a part of the configuration of another embodiment is replaced with another embodiment is also an embodiment of the disclosure.

In the above description, the example in which the light emitted from the light emitting element 20 is the laser pulse light including the high peak value pulse light L1 and the steady oscillation light L2 has been described, but the disclosure is not limited thereto, and for example, the light may be laser light having a peak smaller than that of the high peak value pulse light L1. In this case, the light emitting device according to the present embodiment can suppress ringing of a laser light.

In addition, although an example in which the delay changing unit 110 is combined with the power supply switching unit 60 in which the time constant of the low-pass filter 62 is fixed has been described, the disclosure is not limited thereto, and for example, the delay changing unit 110 may be combined with the power supply switching unit 60A in which the time constant of the low-pass filter 62A is variable.

In addition, although an example in which the low-pass filters 62 and 62A are configured by the resistor and the capacitor has been described, the configuration is not limited thereto, and for example, the low-pass filters may be configured by a coil and a capacitor.

According to the aspect of the embodiments, it is possible to realize a light emitting device and a ranging device capable of easily suppressing emission of undesired light in light emitted from a light emitting element.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-087187, filed May 29, 2024, which is hereby incorporated by reference herein in its entirety.

What is claimed is:

1. A light emitting device comprising:
a light emitting element configured to emit light including a laser light and a steady oscillation light having a light intensity smaller than a light intensity of the laser light;
a light receiving element configured to send a switching signal when receiving a part of the light; and
a power supply control unit configured to control a power supply voltage to be applied to the light emitting element,
wherein the power supply control unit controls the power supply voltage to a first power supply voltage to emit the laser light from the light emitting element, and then controls the power supply voltage to a second power supply voltage smaller than the first power supply voltage in response to the switching signal.

2. The light emitting device according to claim 1, wherein the power supply control unit controls the power supply voltage to the second power supply voltage by disconnecting a path to the light emitting element in response to the switching signal.

3. The light emitting device according to claim 1,
wherein the light emitting element is a laser diode having an anode and a cathode and the power supply voltage corresponds to a voltage between the anode and the cathode, and
wherein the power supply control unit changes a voltage of the cathode from a high level to a low level to emit the laser light, and then changes a voltage of the anode from a high level to a low level in response to the switching signal to control the power supply voltage to the second power supply voltage.

4. The light emitting device according to claim 1, wherein the power supply control unit suppresses the steady oscillation light by controlling the power supply voltage to the second power supply voltage.

5. The light emitting device according to claim 2, wherein the power supply control unit includes a switch circuit configured to disconnect or connect the path in response to the switching signal, and a low-pass filter provided on the path between the switch circuit and the light emitting element.

6. The light emitting device according to claim 5,
wherein the low-pass filter includes a resistor and a capacitor,
wherein the resistor is connected between the switch circuit and the light emitting element, and
wherein a first electrode of the capacitor is connected to a connection node between the resistor and the light emitting element, and a second electrode of the capacitor is connected to ground.

7. The light emitting device according to claim 5, wherein a time constant of the low-pass filter is variable.

8. The light emitting device according to claim 7,
wherein the low-pass filter comprises:
N numbers of resistors connected in series between an input node of the switch circuit and an output node of the light emitting element,
N numbers of capacitors having first electrodes each connected to (N−1) numbers of connection nodes of the N numbers of resistors and the output node, and
N numbers of capacitive switches each connected between second electrodes of the N numbers of capacitors and ground,
wherein the power supply control unit controls each of the N numbers of capacitive switches to be turned on or off.

9. The light emitting device according to claim 1, further comprising a changing unit configured to change a delay time of the switching signal from the light receiving element.

10. The light emitting device according to claim 9,
wherein the changing unit comprises:
a plurality of paths that are formed to have different lengths from each other and transmit the switching signal, and
a selection circuit configured to select one of the plurality of paths based on an emission start timing of the steady oscillation light and a switching timing to the second power supply voltage.

11. The light emitting device according to claim 10, wherein the selection circuit selects the path in advance to make the switching timing coincide with the emission start timing.

12. The light emitting device according to claim 9, wherein the changing unit changes an output impedance of a buffer circuit that outputs the switching signal.

13. The light emitting device according to claim 1, wherein a full width at half maximum of the laser light is 0.1 nsec or less.

14. The light emitting device according to claim 1, further comprising a diffusion unit configured to diffuse the light emitted from the light emitting element to an outside of the light emitting device,
wherein a part of the light enters the light receiving element without passing through the diffusion unit.

15. The light emitting device according to claim 14, further comprising a reflection member configured to reflect a part of the light and guide the part of the light to the light receiving element.

16. The light emitting device according to claim 14, wherein the light emitting element includes a first emission surface that emits the light toward the diffusion unit, and a second emission surface that is different from the first emission surface and emits a part of the light toward the light receiving element.

17. A ranging device comprising:
the light emitting device according to claim 1; and
an acquisition unit configured to acquire information on a distance to an object based on a time difference between a timing at which light is emitted from the light emitting element and a timing at which the light receiving element receives light emitted from the light emitting element and reflected by the object.

18. A movable body comprising:
the ranging device according to claim 17; and
a control unit configured to control the movable body based on the information on the distance acquired by the ranging device.

19. An equipment comprising:
the light emitting device according to claim 1; and
at least one of:
a photoelectric conversion device configured to convert a light signal emitted from the light emitting element and reflected by an object into an electrical signal,
a light device corresponding to the photoelectric conversion device,
a control device configured to control the photoelectric conversion device,
a processing device configured to process a signal output from the photoelectric conversion device,
a display device configured to display information obtained by the photoelectric conversion device,
a storage device configured to store information obtained by the photoelectric conversion device; and
a mechanical device configured to operate based on information obtained by the photoelectric conversion device.
